(19) United States
(12) Patent Application Publication
(10) Pub. No.: US 2025/0239565 A1
(43) Pub. Date: Jul. 24, 2025

(54) PRESSURE SINTERING METHOD AND CORRESPONDING PRESSURE SINTERING APPARATUS

(71) Applicant: BOSCHMAN TECHNOLOGIES B.V., EX DUIVEN (NL)

(72) Inventor: Franciscus Gerardus Johannes BOSCHMAN, EX DUIVEN (NL)

(21) Appl. No.: 18/848,071

(22) PCT Filed: Mar. 23, 2023
(86) PCT No.: PCT/NL2023/050149

§ 371 Date: Sep. 17, 2024

(30) Foreign Application Priority Data
Mar. 23, 2022 (NL) 2031383

(51) Int. Cl. H01L 23/00

(52) U.S. Cl. CPC H01L 24/83; H01L 24/75; H01L 2224/75251; H01L 2224/75252; H01L 2224/75301; H01L 2224/75824; H01L 2224/7598; H01L 2224/83048; H01L 2224/83191; H01L 2224/83203; H01L 2224/8384; H01L 2924/40

(57) ABSTRACT

A pressure sintering method and apparatus are provided for attaching a component to a substrate with a sintering material there between by pressure sintering at a sintering pressure and a sintering temperature during a pressure sintering time interval. The pressure sintering apparatus comprising a first tool part and a second tool part that is configured to hold the substrate, and the first tool part and the second tool part are arranged to be movable with respect to one another in between an open configuration, for receiving the component and the substrate inbetween the first tool part and the second tool part, and a closed configuration, for holding the component and the substrate between and in contact with the first tool part and the second tool part with the sintering material between and in contact with the component and the substrate to apply the sintering pressure to the component, the sintering material and the substrate.

### FIELD OF THE INVENTION

The invention relates to a pressure sintering method for attaching a component to a substrate with a sintering material there between by pressure sintering. The invention further relates to a pressure sintering apparatus for attaching a component to a substrate with a sintering material there between by pressure sintering.

### BACKGROUND OF THE INVENTION

A sintering process is used for producing a device by creating a good bond between a component, such as semiconductor device like a power IC, and a substrate. In known sintering methods and apparatus, the device to be sintered is positioned onto its substrate together with a sintering material in between component and substrate. The substrate with the components can be preheated, for instance, at around 130-150° C., before the actual sintering process. Subsequently, a pressure is applied on the associated component and the sintering material while the device, the sintering material and the substrate are heated to a sintering temperature, for instance, at around 230-300° C., in the sinter tool, so as to complete the sintering process.

In conventional systems, the sintering material, for instance having a paste-like form, is disposed for all devices on the substrate or carrier in one step during the process. In the case of any deficiency, the process should be suspended and the substrate or the carrier needs to be cleaned completely. Since the sintering material is interposed between substrate and component, during preheating, a drying time for the sintering material can cause a time drain in the process. Furthermore, heating up from the preheating temperature to the sintering temperature of the substrate with the components can result in a time consuming process as well.

Additionally, transferring the substrate with the component to the sinter tool must be done slowly and carefully in order to prevent any displacement of the components. In sintering processes and its systems, as referred to above, heating of the sintering material may lead to inhomogeneous effects of the sintering (paste) material and quality issues of the component itself. The quality of the sintering bond between substrate and component depends very much on the actual temperature profile in combination with sintering time and pressure (profiles) during the sintering process. This can become especially crucial for components for which the sinter bond quality is very important. Known processes and systems do show shortcomings and disadvantages.

### SUMMARY OF THE INVENTION

It is an objective of the invention to reduce the time cycle for processing a component.

It is another or alternative objective of the invention to provide a pressure sintering apparatus that can provide fast and uniform drying process for the sintering material on each component.

It is yet another or alternative objective of the invention to provide a pressure sintering apparatus to prevent any displacement of the components on the substrate or the carrier, during transmitting the substrate or carrier with the component to the sinter tool.

It is yet another or alternative object of the invention to provide a pressure sintering apparatus that can provide a well-defined pressure onto each of the component.

In an aspect, the invention provides a pressure sintering method for attaching a component to a substrate with a sintering material there between by pressure sintering at a sintering pressure and a sintering temperature during a pressure sintering time interval for the sintering material to provide a sintering bond between the substrate and the component after pressure sintering, wherein the method comprises
providing a pressure sintering apparatus comprising a first tool part and a second tool part that is configured to hold the substrate, and the first tool part and the second tool part are configured and arranged to be movable with respect to one another in between an open configuration, for receiving the component and the substrate in between the first tool part and the second tool part, and a closed configuration, for holding the component and the substrate between and in contact with the first tool part and the second tool part with the sintering material between and in contact with the component and the substrate to apply the sintering pressure to the component, the sintering material and the substrate and to heat the component, the sintering material and the substrate at the sintering temperature during the pressure sintering time interval;
heating the first tool part and the second tool part to the sintering temperature;
providing the substrate onto the second tool part that has been heated to the sintering temperature, wherein no sintering material has been applied to the substrate, and heating the substrate to the sintering temperature on the second tool part in the open configuration of the first and second tool parts;
maintaining the first tool part and the second tool part with the substrate thereon at the sintering temperature;
applying a sintering material onto the component;
preheating the component with the sintering material applied thereon to a component preheating temperature that is below the sintering temperature;
subsequently, providing the component with the sintering material applied thereon and preheated to the component preheating temperature in between the first tool part and the substrate held on the second tool part in the open configuration of the first and second tool parts, wherein the sintering material applied on the component faces toward the substrate;
subsequently, bringing the first and second tool parts in the closed configuration to hold the component and the substrate between and in contact with the first tool part and the second tool part with the sintering material between and in contact with the component and the substrate to apply the sintering pressure to the component, the sintering material and the substrate and to heat the component, the sintering material and the substrate at the sintering temperature during the pressure sintering time interval; and
subsequently, bringing the first and second tool parts in the open configuration and removing the substrate with the attached component from the second tool part.

According an embodiment, the component with the sintering material applied thereon is provided and held in between the first tool part and the substrate held on the second tool part at a distance from and not in thermal contact with the first tool part and the substrate held on the second tool part in the open configuration of the first tool part and the second tool part.

According an embodiment, the first tool part is arranged above the second tool part, and the first tool part and the second tool part are movable with respect to one another in a vertical direction.

According an embodiment, the first tool part is movable.

According to an embodiment, the second tool part is not movable.

According an embodiment, the component with the sintering material thereon is provided on a carrier that leaves the sintering material exposed, and the carrier holding the component with the sintering material applied thereon is provided in between the first tool part and the second tool part by handling the carrier.

According to an embodiment, the carrier leaves exposed a component side of the component for contacting the first tool part in the closed configuration.

According to an embodiment, the component is held by gravity and/or friction on the carrier.

According to an embodiment, the carrier is moved out of contact with the component in the closed configuration of the first and second tool parts.

According to an embodiment, the carrier is moved further than the component held by the carrier when providing the first tool part and the second tool part in the closed configuration, optionally in the vertical downward direction.

According to an embodiment, the component presents an upper side, and a lower side when provided in between the first tool part and the second tool part, the lower side has the sintering material applied thereon, and the upper side is to be in contact with the first tool part in the closed configuration.

According another embodiment, at least two components are attached to a substrate with a sintering material there between by pressure sintering.

In another aspect, the invention provides a pressure sintering apparatus for attaching a component to a substrate with a sintering material there between by pressure sintering at a sintering pressure and a sintering temperature during a pressure sintering time interval for the sintering material to provide a sintering bond between the substrate and the component after pressure sintering,
wherein the pressure sintering apparatus comprises a first tool part and a second tool part that is configured to hold the substrate, and the first tool part and the second tool part are configured and arranged to be movable with respect to one another in between an open configuration, for receiving the component and the substrate in between the first tool part and the second tool part, and a closed configuration, for holding the component and the substrate between and in contact with the first tool part and the second tool part with the sintering material between and in contact with the component and the substrate to apply the sintering pressure to the component, the sintering material and the substrate and to heat the component, the sintering material and the substrate at the sintering temperature during the pressure sintering time interval,
wherein, in the open configuration, the apparatus is configured to hold the component in between the first tool part and the substrate held on the second tool part with the sintering material applied on the component and directed toward the substrate, and preheated to a component preheating temperature at a distance from and not in thermal contact with the first tool part and the substrate held on the second tool part, and
wherein the apparatus is configured for carrying out at least part of the methods referred to above in relation to the first tool part, the second tool part, and receiving and holding the component in between the first tool part and the second tool part.

According to an embodiment, the apparatus is configured for preheating the component with the sintering material applied thereon to the component preheating temperature.

According to an embodiment, the pressure sintering apparatus comprises a preheating station and a sintering station that comprises the first and second tool parts, the preheating station is configured to preheat the component with the sintering material to the component preheating temperature, and the pressure sintering apparatus is configured for receiving the component with the sintering material preheated to the component preheating temperature, from the preheating station to the sintering station in between the first tool part and the second tool part in the open configuration.

According to an embodiment, the sintering is configured to hold the substrate on the second tool part and to heat the substrate to the sintering temperature on the second tool part.

According to an embodiment, the component is held on a carrier and the apparatus is configured for transferring the carrier from the preheating station to the sintering station.

According to an embodiment, the first tool part is configured for holding the carrier.

According to another embodiment, the pressure sintering apparatus is configured for attaching at least two components to a substrate with a sintering material there between by pressure sintering.

In another aspect, the invention provides for a carrier for holding at least one component for use in the above mentioned apparatus or the.

According to an embodiment, the carrier comprises a thermally insulating material.

### BRIEF DESCRIPTION OF THE DRAWINGS

Further features and advantages of the invention will become apparent from the description of the invention by way of non-limiting and non-exclusive embodiments. These embodiments are not to be construed as limiting the scope of protection. The person skilled in the art will realize that other alternatives and equivalent embodiments of the invention can be conceived and reduced to practice without departing from the scope of the present invention. Embodiments of the invention will be described with reference to the accompanying drawings, in which like or same reference symbols denote like, same or corresponding parts, and in which;

FIG. 1 shows schematic view of an apparatus for attaching a sintering material onto the component prior to a pressure sintering apparatus;

FIGS. 2A, 2B, 2C and 2D show schematic views of a pressure sintering apparatus having a component and a substrate being provided in first and second tool parts, respectively, and their configurations with respect to each other, for attaching a component to a substrate with a sintering material there between by pressure sintering;

FIGS. 3A, 3B, 3C, 3D and 3E show schematic views of a pressure sintering apparatus having a component being held by a carrier and provided in a first tool part and a substrate being provided a second tool part, and their configurations with respect to each other, for attaching a component to a substrate with a sintering material there between by pressure sintering;

FIG. 4 schematically shows a cross section of a pressure sintering processing apparatus with a first tool part and second tool part having a heating arrangement;

FIG. 5A schematically shows a cross section of a pressure sintering processing apparatus with a first tool part having a plurality of insert members and a second tool part, before a component in the first tool part and a substrate in the second tool part are brought together; and

FIG. 5B schematically shows a cross section of a pressure sintering processing apparatus with a first tool part having a plurality of insert members and a second tool part, when a component in the first tool part and a substrate in the second tool part are brought together.

### DETAILED DESCRIPTION OF EMBODIMENTS

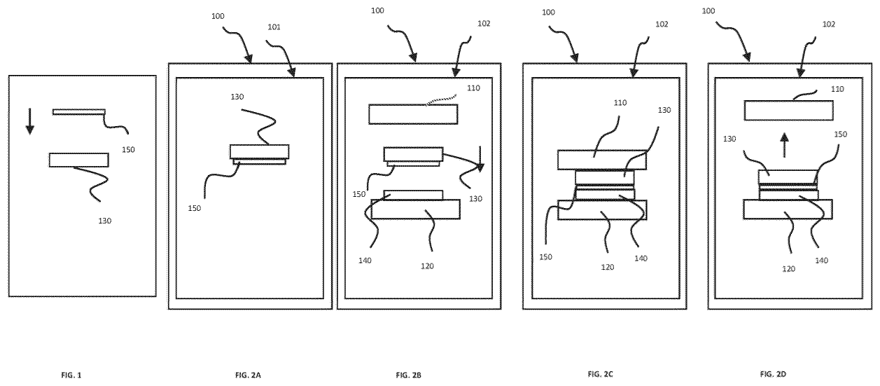

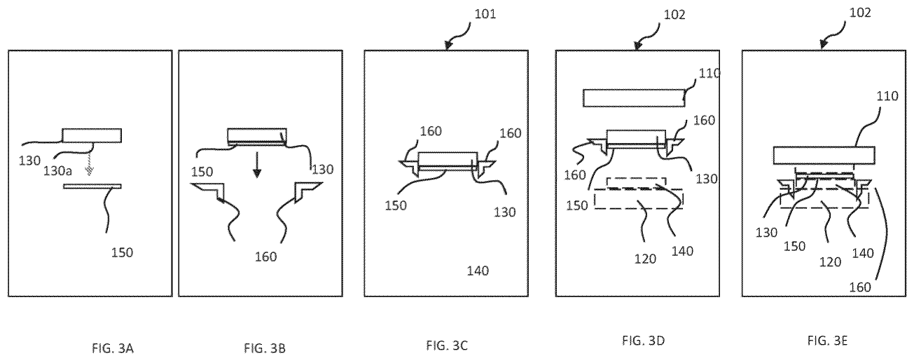

FIGS. 2A, 2B, 2C and 2D schematically show a preheating station 101 and a sintering station 102 of a pressure sintering apparatus 100, and various process steps according to an embodiment of the invention. FIG. 1 shows an additional step done in an additional apparatus prior to the sintering apparatus in order to attach the sintering material onto the component and the process steps done therein. The sintering station 102 of the sintering apparatus 100 comprises a first tool part 110 for holding a component 130, and a second tool part 120 for holding a substrate 140. The first tool part 110 and the second tool part 120 are configured and arranged to be movable with respect to one another to apply a pressure to the component 130 and the substrate 140 held between the first 110 and second 120 tool parts with a sintering material 150 between the component and the substrate, and allow heating the component and substrate at a sintering temperature in the pressure sintering steps.

Prior to entering the sintering apparatus 100, a sintering material 150 is applied to an attachment surface 130a of the component 130, as is schematically shown in FIG. 1. The component 130 is to be attached with its attachment surface to the substrate 140 by pressure sintering. Generally, the sintering material 150, such as a sintering paste, is applied to the component 130 in a machine that is dedicated and laid out for that purpose. Subsequently, the component 130 with the sintering material 150 applied thereto is provided to the preheating station 101 of the sintering apparatus 100. Multiple components 130 can be arranged on a carrier in a section of the preheating station 101 for preheating to a component preheating temperature, which can be in the range of 130-150° C. Since the component 130 will be held on the first tool part 110 and processed in the sintering station 102 with the attachment surface 130a of the component 130 and the sintering material 150 applied thereto facing downward towards the substrate 140 held on the second tool part 120, the component 130 is handled and preheated with the sintering material 150 applied thereto facing downward as well in the preheating station 101. Meanwhile, the substrate 140 is preheated in the sintering station 102 to a sintering temperature, which will be the temperature required for the pressure sintering step. The temperature required for the pressure sintering step can be in the range of 200-300° C. dependent on the specific application and sintering material 150 employed. Only one substrate 140 and one component 130 are shown in FIGS. 1 and 2A to 2D for illustration purposes. As briefly indicated, multiple components 140 held in one or more carriers and with a sintering material applied to the components could be processed collectively in a pressure sintering process in the pressure sintering station for attachment to one or more substrates.

FIG. 2B schematically shows an open configuration of the first tool part 110 and the second tool part with respect to each other, before the component 130 and the substrate 140 are brought together. The first tool part 110 is configured to hold the component 130 with the sintering material 150 preheated to the component preheating temperature. As shown in FIG. 2B, the component 130 with the sintering material 150 is arranged to be facing the substrate 140 held on the second tool part 120, in the open configuration of the sintering station 102. In an embodiment, as shown in FIG. 2B, in the open configuration, the apparatus 100 is configured to hold the component 130 in between the first tool part 110 and the substrate 140 held on the second tool part 120 with the sintering material applied 150 on the component 130 and directed toward the substrate 140. The component 130 with the sintering material 150 preheated to the component preheating temperature, is arranged at a distance from and not in thermal contact with the first tool part 110 and the substrate 140 held on the second tool part 120, in the open configuration.

The preheating of the component(s) with the sintering material applied on the respective attachment surface(s) 130a of the lower side of the component serves two different purposes: pre-drying the sintering material and preheating the components before the actual press sintering process. In that way, the sintering material has been pre-dried before the actual press sintering process, to evaporates an organic capping agent in the sintering material and to better allow the nanoparticles in the sintering material to fuse together during the press sintering process later. Preheating the component(s) 130 with the sintering material 150 in a preheating station 101 of the sintering apparatus 100 will provide a reduced time cycle of the sintering process, especially in the sintering station 102.

In the exemplary embodiment as shown in FIG. 2B, the substrate 140 is heated on the second tool part 120 to the sintering temperature, especially to the temperature of, for instance, 300° C. The first and second tool parts 110, 120 of the pressure sintering apparatus 100 have been heated earlier to the sintering temperature and are maintained at the sintering temperature. Therefore, the substrate 140 is maintained as well at the sintering temperature on the second tool part.

FIG. 2C schematically shows a closed configuration of the first tool part 110 and the second tool part 120 with respect to each other, when the component 130 and the substrate 140 have been brought together. In the embodiment as shown in FIG. 2C, the first tool part 110 is configured to be lowered onto the upper side of the component 130 having the sintering material 150 so as to attach the component to the substrate with the sintering material there between. Initially, the component 130 with the sintering material is held at a distance from the substrate and the first tool part. When lowering the component and the first tool part, the component may first contact the substrate after which the first tool part contacts the component, or the first tool part may first contact the component after which both are further lowered for the component to contact the substrate, or the component and the first tool part can both be lowered such that the component contacts the substrate and the first tool part at the same moment. In FIG. 2C, in the closed configuration, the first tool part 110 and the second tool part 120 are arranged for holding there between the component 130 and the substrate 140 with the sintering material 150.

In the process step of the embodiment as shown in FIG. 2C, after the component(s) 130 with the sintering material 150 have been held for a selected time at the preheating temperature (for instance, 140° C.) and a desired drying of the sintering material is achieved and the component(s) has been provided in between the first and second tool parts, the first and second tool parts 110, 120 are moved to bring the substrate 140 and the components 130 with the sintering material together, in order to start the pressure sintering process at a selected sintering pressure applied by the first and second tool parts. The first tool part 110 is configured to lower the component 130 relative to the second tool part 120, in order to bring the heated substrate 140 and the component 130 together, to attach the component 130 to the substrate 140 by pressure sintering the sintering material between the component 130 and the substrate 140.

During the pressure sintering process, the heated substrate 140 and the first tool part are in thermal contact with the heated component 130, and the substrate 140 and first tool part now rapidly transfer heat to the component 130. The sintering pressure applied to the component 130 together with the substrate 140, can be in the order of, for instance, 10-15 MPa, at the sintering temperature of, for instance, 300° C. When the component 130 is brought into contact with the substrate 140 and the first tool part in the pressure sintering process step of FIG. 2C, the temperature of the component 130 with the sintering material 150 ramps up very rapidly from the preheating (first predetermined) temperature of, for instance, 140° C. to the sintering temperature of, for instance, 300° C. The temperature increase of the component and sintering material from the preheating temperature to the sintering temperature is virtually instantaneous in view of the thermal mass of the component and the thermal masses of substrate and first and second tool parts. In order to provide a homogenous process and resulting sinter bond, the afore mentioned sintering pressure and temperature should be maintained during a predetermined time interval of, for instance, 180 seconds to 250 seconds. Therefore, after bringing the heated substrate 140 and the component 130 together, the substrate 140 is held at the sintering temperature of, for instance, 300° C.

FIG. 2D schematically shows a configuration of the first tool part 110 and the second tool part 120 moved apart with respect to each other, after the pressure sintering process step of FIG. 2C, so after completing the attachment of the component 130 to the substrate 140 by pressure sintering the sintering material 150 there between. As shown, after the pressure sintering process, the first tool part moves away in a vertical direction from the component 130 that is now attached to the substrate 140, and elevates with respect to the second tool part 120 to bring the first and second tool parts in the open configuration. The second tool part is static and not movable.

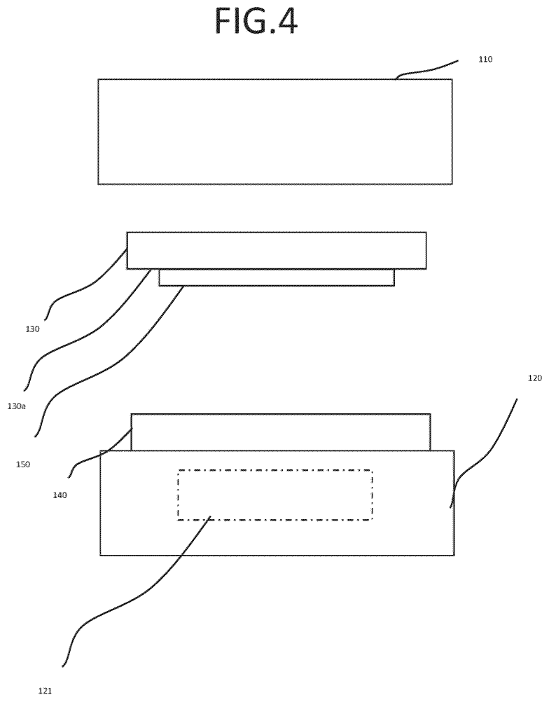

FIGS. 3A, 3B, 3C, 3D and 3E schematically show a sequence of handling the component within the sintering tool using a carrier 160 for the component(s) 130. FIG. 3A schematically shows applying the sintering material 150 to the attachment surface 130a of the component, which can be done in tooling dedicated for that purpose. Subsequently, the component 130 with the sintering material is provided on a carrier 160, which can be a plastic frame, as is shown in FIG. 3B. The carrier leaves the side of the component with the sintering material thereon exposed, and thus the sintering material not covered and exposed, and leaves the upper side of the component exposed for contacting the first tool part. The component(s) can be held by gravity and/or friction on the carrier. For instance, a component can be held by friction by sides or protrusions from sides of an opening of the carrier in the opening. Tabs can be provided onto which the component is supported can be provided as well, or any combination of means for holding by gravity and friction.

The steps of FIGS. 3A and 3B are generally done outside the sintering apparatus 100. Multiple components 100 can be placed in a single carrier 160 for simultaneous processing in the sintering apparatus 100. FIG. 3C shows that the carrier 160 with the component(s) 130 is provided in the preheating station 101 of the sintering apparatus as has been discussed with reference to FIG. 2A above. The component(s) are preheated to their respective preheating temperatures as discussed earlier. The substrate 140 is provided on the second tool part 120 that has been heated to and is maintained at the sintering temperature. After the preheating, the carrier 160 with the component(s) 130 having the sintering material 150 applied thereto is provided to a position intermediate the first tool part 101 and the substrate 140 on the second tool part 102, as is shown in FIG. 3D. The second tool part 120 with the substrate 140 thereon is held at the sintering temperature, while the carrier 160 with the components 130 is at a lower temperature corresponding to the component preheating temperature. Subsequently, the first and second tool part 110, 120 are closed by moving the first tool part 110 in a vertical direction downward toward the second tool part 120, while the carrier 160 with the component(s) is moved downward as well, as is schematically shown in FIG. 3E. Multiple components 130 can be provided onto a single substrate 140, and/or on multiple substrates, from a single carrier 160. The component(s) are heated virtually instantaneously to the sintering temperature of the first and second tool parts and the substrate since the thermal mass of the component(s) with the sintering material 150 will be much smaller than the thermal mass of the first and second tool parts and the substrate. Pressure sintering of the sintering material 150 will thus proceed immediately when the first and second tool parts are closed. After the predetermined sintering time the first and second tool parts are opened as has been discussed with reference to FIG. 2D. FIG. 3E shows that the carrier 160 has moved further downward than the component 130 as soon as the component 130 is supported by the substrate 140 so that the component has come free from the carrier.

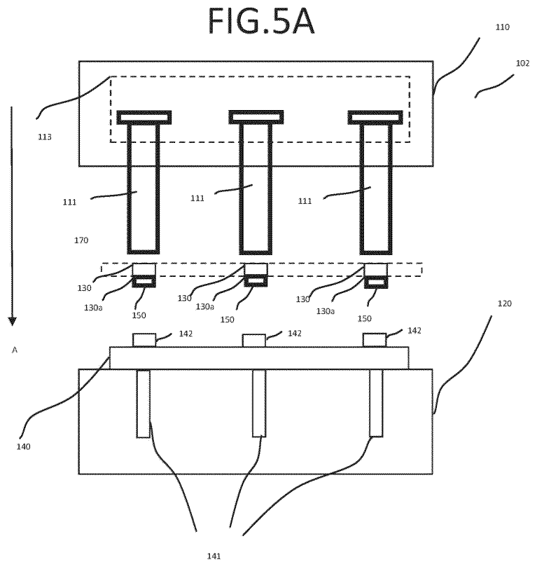

FIG. 4 schematically shows a cross section of the pressure sintering apparatus 100. The pressure sintering apparatus 100 comprises the first tool part 110 for contacting the component 130, and the second tool part 120 for holding the substrate 140. The second tool part 120 comprises a heating arrangement 122 to heat the second tool part and the substrate 140 to the sintering temperature. The first tool part is heated as well in the sintering apparatus, but the heating means are not shown but are known as such.

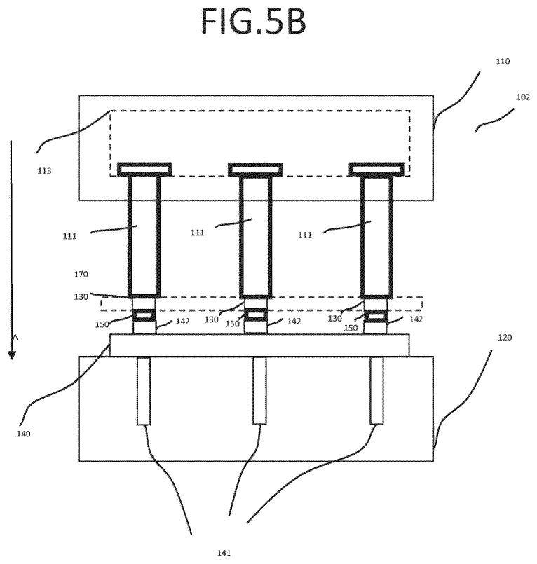

FIGS. 5A and 5B shows schematically a cross section of an embodiment of the pressure sintering apparatus 100, especially of the sintering station 102. The apparatus 100 comprises the first tool part 110 having at least one dynamic insert member 111 coupled to a pressure chamber 113 of the first tool part 110. When an the pressure chamber 113 is pressurised with a gas under pressure, a force is applied onto the dynamic insert members 111 of the first tool part to exert force on the associated components 130 along the direction A. Each insert member 111 is associated with a component 130 with the sintering material 150 on the attachment surface 130a of the component 130. A heating block can be provided around the insert members for heating thereof to the sintering temperature. The apparatus 100 of FIGS. 5A and 5B further comprises the second tool part 120 configured to hold the substrate 140, which in the embodiment shown has a plurality of cooling fins 141. FIG. 5A shows a configuration of the first tool part 110 and the second tool part with respect to each other, before the component 130 and the substrate 140 are brought together, and with a carrier 160 holding components 130 thereon. In this configuration of the apparatus 100, the insert members 111 are in a retracted position with respect to the first tool part 110. The substrate has, in the embodiment shown, at least one pedestal 142 each of that receives a respective component 130 and lifts the respective component from the carrier 160. The pedestal(s) allows the carrier to move somewhat further down so that the component is free from the carrier and an appropriate force for pressure sintering of the sintering material 150 will be applied to the component(s) 130 and the substrate 140.

The insert members 111 are displaceable in a direction that is substantially perpendicular to the surface 130a of the associated component 130 contacted by the insert member 111, which is the direction A in FIG. 5A. The configuration of FIG. 5A corresponds to the one shown in FIG. 3D.

FIG. 5B shows a configuration of the first tool part 110 and the second tool part 120, with respect to each other, when the component 130 and the substrate 140 are brought together, and corresponds to the one shown in FIG. 3E.

One can arrive from the configuration of FIG. 5A to the configuration of FIG. 5B by bringing the first and second tool parts together and pressurising the pressure chamber 113. When the first 110 and second tool part 120 have been brought together, a force is applied onto each component 130 with the sintering material 150, via the respective insert 111, along the pressure direction A, by pressurising the pressure chamber 313.

The component 130 as referred to above can be a semiconductor product of various kinds, which are generally manufactured using semiconductor manufacturing technologies. It can comprise chips, power ICs, sensors, MEMs, LEDs, etcetera and combinations thereof.

1. A pressure sintering method for attaching a component (130) to a substrate (140) with a sintering material (150) there between by pressure sintering at a sintering pressure and a sintering temperature during a pressure sintering time interval for the sintering material to provide a sintering bond between the substrate and the component after pressure sintering, wherein the method comprises
providing a pressure sintering apparatus comprising a first tool part (110) and a second tool part (120) that is configured to hold the substrate (140), and the first tool part (110) and the second tool part (120) are configured and arranged to be movable with respect to one another in between an open configuration, for receiving the component (130) and the substrate (140) in between the first tool part and the second tool part, and a closed configuration, for holding the component and the substrate between and in contact with the first tool part and the second tool part with the sintering material (150) between and in contact with the component and the substrate to apply the sintering pressure to the component, the sintering material and the substrate and to heat the component, the sintering material and the substrate at the sintering temperature during the pressure sintering time interval;
heating the first tool part (110) and the second tool part (120) to the sintering temperature;
providing the substrate onto the second tool part that has been heated to the sintering temperature, wherein no sintering material has been applied to the substrate, and heating the substrate (140) to the sintering temperature on the second tool part in the open configuration of the first and second tool parts;
maintaining the first tool part and the second tool part with the substrate thereon at the sintering temperature;
applying a sintering material onto the component;
preheating the component with the sintering material applied thereon to a component preheating temperature that is below the sintering temperature;
subsequently, providing the component with the sintering material applied thereon and preheated to the component preheating temperature in between the first tool part and the substrate held on the second tool part in the open configuration of the first and second tool parts, wherein the sintering material applied on the component faces toward the substrate;
subsequently, bringing the first and second tool parts in the closed configuration to hold the component and the substrate between and in contact with the first tool part and the second tool part with the sintering material (150) between and in contact with the component and the substrate to apply the sintering pressure to the component, the sintering material and the substrate and to heat the component, the sintering material and the substrate at the sintering temperature during the pressure sintering time interval; and
subsequently, bringing the first and second tool parts in the open configuration and removing the substrate with the attached component from the second tool part.

2. The method according to claim 1, wherein the component (130) with the sintering material (150) applied thereon is provided and held in between the first tool part (110) and the substrate (140) held on the second tool part (120) at a distance from and not in thermal contact with the first tool part (110) and the substrate (140) held on the second tool part (120) in the open configuration of the first tool part and the second tool part.

3. The method according to claim 1, wherein the first tool part (110) is arranged above the second tool part (120), and the first tool part and the second tool part are movable with respect to one another in a vertical direction.

4. The method according to claim 1, wherein the first tool part (110) is movable.

5. The method according to claim 4, wherein the second tool part (120) is not movable.

6. The method according to claim 1, wherein the component (130) with the sintering material thereon is provided on a carrier (160) that leaves the sintering material exposed, and the carrier holding the component with the sintering material applied thereon is provided in between the first tool part (110) and the second tool part (120) by handling the carrier.

7. The method according to claim 6, wherein the carrier (160) leaves exposed a component side of the component for contacting the first tool part (110) in the closed configuration.

8. The method according to claim 6, wherein the component is held by gravity and/or friction on the carrier.

9. The method according to claim 6, wherein the carrier is moved out of contact with the component in the closed configuration of the first and second tool parts.

10. The method according to claim 9, wherein the carrier is moved further than the component held by the carrier when providing the first tool part and the second tool part in the closed configuration, optionally in the vertical downward direction.

11. The method according to claim 1, wherein the component presents an upper side, and a lower side when provided in between the first tool part and the second tool part, the lower side has the sintering material applied thereon, and the upper side is to be in contact with the first tool part in the closed configuration.

12. The method according to claim 1, wherein at least two components (130) are attached to a substrate (140) with a sintering material (150) there between by pressure sintering.

13. A pressure sintering apparatus (100) for attaching a component (130) to a substrate (140) with a sintering material (150) there between by pressure sintering at a sintering pressure and a sintering temperature during a pressure sintering time interval for the sintering material to provide a sintering bond between the substrate and the component after pressure sintering,
wherein the pressure sintering apparatus comprises a first tool part (110) and a second tool part (120) that is configured to hold the substrate (140), and the first tool part (110) and the second tool part (120) are configured and arranged to be movable with respect to one another in between an open configuration, for receiving the component (130) and the substrate (140) in between the first tool part and the second tool part, and a closed configuration, for holding the component and the substrate between and in contact with the first tool part and the second tool part with the sintering material (150) between and in contact with the component (130) and the substrate (140) to apply the sintering pressure to the component (130), the sintering material (150) and the substrate (140) and to heat the component, the sintering material and the substrate at the sintering temperature during the pressure sintering time interval,
wherein, in the open configuration, the apparatus is configured to hold the component in between the first tool part and the substrate held on the second tool part with the sintering material applied on the component and directed toward the substrate, and preheated to a component preheating temperature at a distance from and not in thermal contact with the first tool part and the substrate held on the second tool part, and
wherein the apparatus is configured for carrying out at least part of the method according to any one of the preceding claims in relation to the first tool part, the second tool part, and receiving and holding the component in between the first tool part and the second tool part.

14. The apparatus (100) according to claim 13, wherein the apparatus is configured for preheating the component with the sintering material applied thereon to the component preheating temperature.

15. The apparatus (100) according to claim 14, wherein the pressure sintering apparatus (100) comprises a preheating station (101) and a sintering station (102) that comprises the first and second tool parts (110, 120), the preheating station (101) is configured to preheat the component (130) with the sintering material (150) to the component preheating temperature, and the pressure sintering apparatus is configured for receiving the component (130) with the sintering material (150) preheated to the component preheating temperature, from the preheating station (101) to the sintering station (102) in between the first tool part (110) and the second tool part (120) in the open configuration.

16. The apparatus (100) according to claim 15, wherein the sintering station (102) is configured to hold the substrate on the second tool part (120) and to heat the substrate (140) to the sintering temperature on the second tool part (120).

17. The apparatus (100) according to claim 15, wherein the component is held on a carrier (160) and the apparatus (100) is configured for transferring the carrier (160) from the preheating station (101) to the sintering station (102).

18. The apparatus (100) according to claim 17, wherein the first tool part (110) is configured for holding the carrier (160).

19. The apparatus (100) according to claim 13, wherein the pressure sintering apparatus is configured for attaching at least two components (130) to a substrate (140) with a sintering material (150) there between by pressure sintering.

20. A carrier (160) for holding at least one component for use in the apparatus (100) according to claim 17, or a method, of the pressure sintering method for attaching a component (130) to a substrate (140) with a sintering material (150) there between by pressure sintering at a sintering pressure and a sintering temperature during a pressure sintering time interval for the sintering material to provide a sintering bond between the substrate and the component after pressure sintering, wherein the method comprises
providing a pressure sintering apparatus comprising a first tool part (110) and a second tool part (120) that is configured to hold the substrate (140), and the first tool part (110) and the second tool part (120) are configured and arranged to be movable with respect to one another in between an open configuration, for receiving the component (130) and the substrate (140) in between the first tool part and the second tool part, and a closed configuration, for holding the component and the substrate between and in contact with the first tool part and the second tool part with the sintering material (150) between and in contact with the component and the substrate to apply the sintering pressure to the component, the sintering material and the substrate and to heat the component, the sintering material and the substrate at the sintering temperature during the pressure sintering time interval;
heating the first tool part (110) and the second tool part (120) to the sintering temperature;
providing the substrate onto the second tool part that has been heated to the sintering temperature, wherein no sintering material has been applied to the substrate, and heating the substrate (140) to the sintering temperature on the second tool part in the open configuration of the first and second tool parts;
maintaining the first tool part and the second tool part with the substrate thereon at the sintering temperature;
applying a sintering material onto the component;
preheating the component with the sintering material applied thereon to a component preheating temperature that is below the sintering temperature;
subsequently, providing the component with the sintering material applied thereon and preheated to the component preheating temperature in between the first tool part and the substrate held on the second tool part in the open configuration of the first and second tool parts, wherein the sintering material applied on the component faces toward the substrate;
subsequently, bringing the first and second tool parts in the closed configuration to hold the component and the substrate between and in contact with the first tool part and the second tool part with the sintering material (150) between and in contact with the component and the substrate to apply the sintering pressure to the component, the sintering material and the substrate and to heat the component, the sintering material and the substrate at the sintering temperature during the pressure sintering time interval; and
subsequently, bringing the first and second tool parts in the open configuration and removing the substrate with the attached component from the second tool part;
wherein the component (130) with the sintering material thereon is provided on a carrier (160) that leaves the sintering material exposed, and the carrier holding the component with the sintering material applied thereon is provided in between the first tool part (110) and the second tool part (120) by handling the carrier.

21. The carrier according to claim 20, wherein the carrier comprises a thermally insulating material.
